(19) United States
(12) Patent Application Publication
(10) Pub. No.: US 2012/0247956 A1
(43) Pub. Date: Oct. 4, 2012

(54) BIOSENSOR STRIP AND MANUFACTURING METHOD THEREOF

(75) Inventors: TAI-CHENG CHOU, Shulin City (TW); Chai-chi Wu, Kaohsiung City (TW); Chia-Chin Yang, Luzhu Township (TW); Chao-Wang Chen, Taipei City (TW)

(73) Assignee: TAIDOC TECHNOLOGY CORPORA

(21) Appl. No.: 13/078,088

(22) Filed: Apr. 1, 2011

(51) Int. Cl. G01N 27/327; C23C 14/06; B23K 26/00; C23C 14/34

(52) U.S. Cl. 204/403.01; 427/569; 219/121.69; 219/121.67

(57) ABSTRACT

The present invention is related to a biosensor strip and a manufacturing method thereof. The biosensor strip comprises an electrode layer that has a first electrode pattern and a second electrode pattern. The two electrode patterns are provided on a base by different manufacturing methods. The first electrode pattern is made by a first electrically conductive material that may consist of precious metal and the second electrode pattern is made by a second electrically conductive material that may not consist of precious metal.

### BACKGROUND OF THE INVENTION

1. Field of the Invention

The present invention relates in general to a biosensor strip and a manufacturing method thereof. More particularly, the present invention relates to a biosensor strip and a manufacturing method thereof for forming electrode patterns to contact a reaction reagent by sputtering coated and forming other electrode patterns without contacting the reaction reagent by other method.

2. Description of the Related Art

Since the improvement of the science and technology, many tests can be operated by users at home. In the market, many disposable strips are used for measuring specific components in a biological fluid and can be operated by users in house. Analytical biosensor strips are useful in chemistry and medicine to determine the presence and concentration of a biological analyte. Such strips are needed, for example, to monitor glucose in diabetic patients and lactate during critical care events. In the recent year, Diabetes is a modern disease, especially in elders. Most people need an accuracy measurement of blood glucose.

Conventional electrochemical biosensor strip has a base, an electrode system, an insulating substrate, a test reagent and a cover. The electrode system is laid on the base and comprises two electrodes separated from each other. The insulating substrate is laid down onto the electrode system and has a first opening and a second opening. The first opening exposes portions of the electrode system for electrical connection with a meter, which measures some electrical property of a test sample after the test sample is mixed with the test reagent of the strip. The second opening exposes a different portion of the electrode system for application of the test reagent to those exposed surfaces of electrode system. The test reagent is a reagent that is specific for the test to be performed by the strip. The test reagent may be applied to the entire exposed surface area of the electrode system in the area defined by the second opening. The cover is covered on the electrode system and the test reagent for protecting the test reagent.

Different methods are well known for manufacturing the electrode system on the base, for example screen printing, sputtering coated, evaporation and so on. However, the electrode system formed by screen printing techniques can only be formed from composition that are both electrically conductive and which are screen printable. Furthermore, screen printing techniques only allow for the reliable formation of structures and patterns having a feature size greater than 75 μm. Therefore, sputtering coated of gold and then through a laser etching for removing partial gold can solve the above question to form the structures and patterns having a feature size less than 75 μm. However, all electrode system made by sputtering coated added laser etching would increase manufacturing cost, and especially gold is an expensive material. Besides, sputtering coated method has a disadvantage that a mask used in sputtering coated process would progressively deposited more and more sputtering materials thereon after used time and time again. The needed sputtering zone after using the same mask several rounds will be smaller. That is saying, if all electrode system is made by sputtering coated, the desired electrode system will have different size which will influence the accuracy of the biosensor strip.

Thus, a biosensor strip and a manufacturing method thereof are needed by the manufacture that will achieve for accurately measuring blood glucose and costing inexpensively and preventing from above disadvantages. It is an aspect of the present invention to provide such a biosensor strip and a manufacturing method thereof.

### SUMMARY OF THE INVENTION

In order to solve the above noted conventional problems, one aspect of the present invention is to provide a biosensor strip and a manufacturing method that achieve for manufacturing easily and costing inexpensively. In a preferred embodiment of the present invention, the biosensor strip is an electrochemical biosensor strip.

In one aspect, the present invention is a method of manufacturing a biosensor strip, the method comprising the steps of:

providing a first electrically conductive material on a base to form a first electrode pattern;

providing a second electrically conductive material on the base by sputtering coating;

partially removing the second electrically conductive material to form a second electrode pattern;

extending a cover over the base, the cover and the base cooperating to define a sample-receiving chamber that comprises a reaction reagent; and

the second electrode pattern is sized and positioned in the sample-receiving chamber.

Preferably, the second electrically conductive material may be consisting of a precious metal and the first electrically conductive material may be not consisting of a precious metal.

In a preferred embodiment of the present invention, the first electrically conductive material is provided on the base by a method except sputtering coating.

The first electrically conductive material employed in the present invention maybe screen printed on the base. Preferably, the first electrode pattern is formed almost corresponding to outside the sample-receiving chamber. More preferably, the first electrode pattern is formed corresponding to outside the sample-receiving chamber and protruding a portion in the sample-receiving chamber.

In a preferred embodiment of the present invention, partially removing the second electrically conductive material may be using laser etching.

In another preferred embodiment of the present invention, a length of the second electrode pattern parallel to one end of the biosensor strip is greater than a width of the sample-receiving chamber. Preferably, a portion of the first electrode pattern and a portion of the second electrode pattern are overlap. More preferably, the overlap portion of the first electrode pattern and the second electrode pattern is positioned in a border of the sample-receiving chamber.

In another aspect, the present invention is a method of making a biosensor electrode pattern, comprising:

providing a first electrically conductive material on a base to form a first electrode pattern;

providing a second electrically conductive material which is not the same with the first electrically conductive material on the base by sputtering coating;

partially removing the second electrically conductive material from the base to form a second electrode pattern.

Preferably, the second electrode pattern is positioned suitable to contact a sample for detecting an analyte in the sample and partially removing the second electrically conductive material is using laser etching.

In a preferred embodiment of the present invention, the first electrically conductive material is screen printed on the base and the first electrode pattern is positioned almost corresponding to outside the second electrode pattern. Preferably, a portion of the first electrode pattern and a portion of the second electrode pattern are overlap. More preferably, the second electrically conductive material is consisting of a precious metal and the first electrically conductive material is not consisting of a precious metal.

In still another aspect, the present invention is a method of making a biosensor electrode pattern, comprising:

printing a first electrically conductive material on a flexible insulating substrate to form a first electrode pattern;

sputtering coating a second electrically conductive material on the flexible insulating substrate; and

ablating through a portion of the second electrically conductive material with a laser, to form a second electrode pattern.

In a preferred embodiment of the present invention, the second electrode pattern is defined to contact a sample for detecting an analyte in the sample. Preferably, the second electrically conductive material is consisting of a precious metal and the first electrically conductive material is not consisting of a precious metal.

In yet another aspect, the present invention is a method of making a biosensor strip, comprising:

forming an electrode set by the previously described method; and

cutting said substrate, to form a strip.

In yet another aspect, the present invention is a biosensor strip comprising:

a base formed to include a first surface;

an electrode layer formed on the first surface;

a cover cooperating with the base to define a sample-receiving chamber; and

a reaction reagent coated on at least a portion of the sample-receiving chamber, and the sample-receiving chamber of the cover having a sample opening and sized to transport a liquid sample from the opening to the reaction reagent;

the electrode layer comprises a first electrode pattern made by a first electrically conductive material positioned corresponding to outside the sample-receiving chamber, and a second electrode pattern made by a second electrically conductive material positioned corresponding to the sample-receiving chamber; and

the second electrically conductive material is consisting of a precious metal and the first electrically conductive material is not consisting of a precious metal.

In a preferred embodiment of the present invention, the first electrically conductive material is screen printed on the base and the second electrically conductive material is sputtering coating on the base.

In a preferred embodiment of the present invention, the second electrically conductive material sputtering coating on the base is then partially removed by laser etching to form the second electrode pattern.

Preferably, a portion of the first electrode pattern and a portion of the second electrode pattern are overlap.

A length of the second electrode pattern employed in the present invention parallel to one end of the biosensor strip is preferably greater than a width of the sample-receiving chamber.

An advantage of the present invention is that it allows for manufacturing easily and costing inexpensively.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The following drawings form part of the present specification and are included to further demonstrate certain aspects of the present invention. The invention may be better understood by reference to one or more of these drawings in combination with the detailed description of specific embodiments presented herein:

FIG. 1 is a perspective view of a first embodiment of a biosensor strip in accordance with the present invention;

FIG. 2 is an exploded perspective view of the biosensor strip of FIG. 1;

FIGS. 3A to 3D are schematic plan views of a biosensor electrode set of the present invention in different manufacturing steps;

FIG. 4 is a schematic plan view of a sheet of biosensor strips; and

FIG. 5 is a block diagram of a process of the present invention for making a biosensor strip of the present invention.

### DESCRIPTION OF THE PREFERRED EMBODIMENTS

For the purposes of promoting an understanding of the principles of the invention, reference will now be made to the embodiment illustrated in the drawings, and specific language will be used to describe that embodiment. It will nevertheless be understood that no limitation of the scope of the invention is intended. Alterations and modifications in the illustrated device, and further applications of the principles of the invention as illustrated therein, as would normally occur to one skilled in the art to which the invention relates are contemplated, are desired to be protected. In particular, although the invention is discussed in terms of a blood glucose strip, it is contemplated that the invention can be used with devices for measuring other analytes and other sample types. Such alternative embodiments require certain adaptations to the embodiments discussed herein that would be obvious to those skilled in the art.

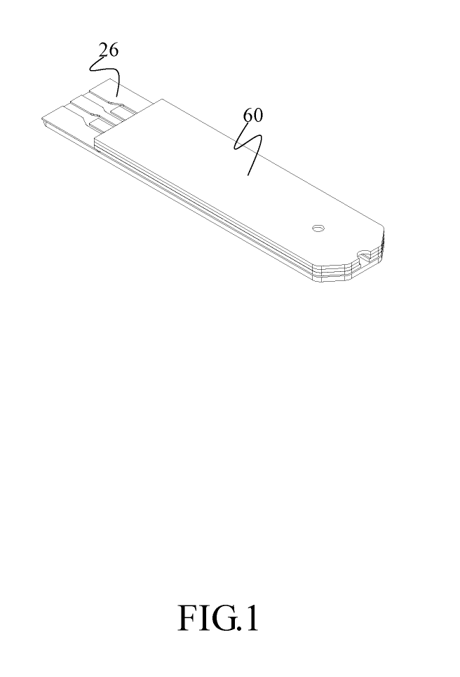

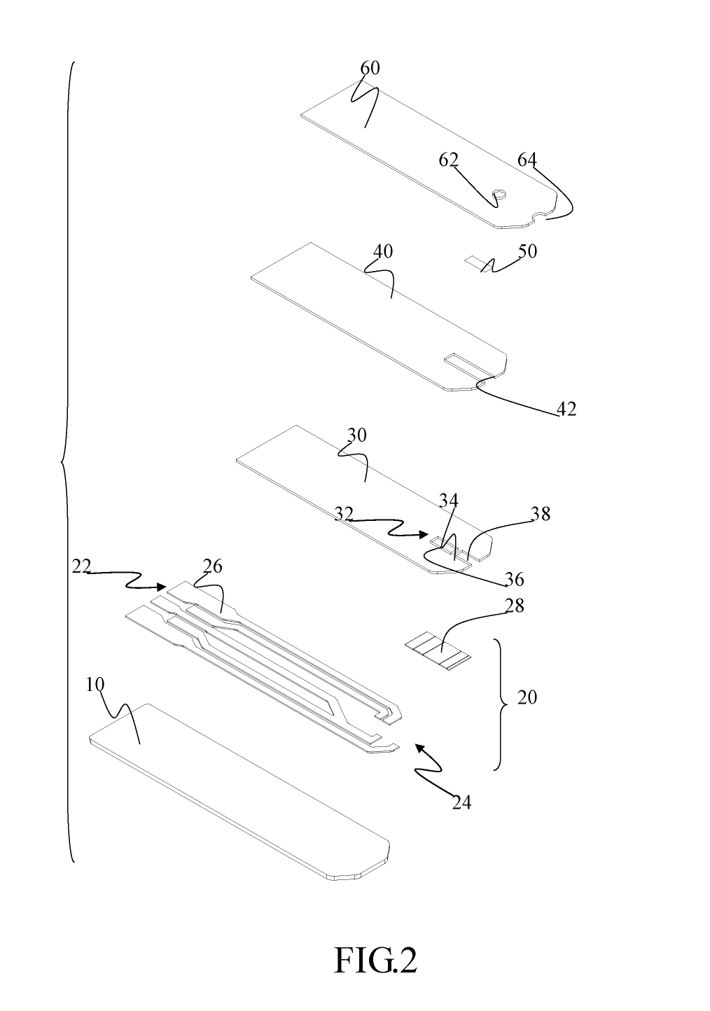

Although a system and method of the present invention may be used with biosensor strips having a wide variety of designs and made with a wide variety of construction techniques and processes, a typical biosensor strip, especially an electrochemical biosensor strip, is illustrated in FIGS. 1 and 2. With reference to FIGS. 1 and 2, they show a perspective and exploded perspective view of a first embodiment of a biosensor strip in accordance with the present invention. The biosensor strip of the present invention comprises a base (10), an electrode layer (20), a spacer (30), a reaction reagent (50) and a cover (60).

The base (10) can be preferably an insulating substance and has electrical insulating characteristic.

The electrode layer (20) is laid on the base (10) and comprises a first end (22), a second end (24) and electrode patterns. The first end (22) of the electrode layer (20) is used for contact with a mating biosensing meter and the second end (24) of the electrode layer (20) is used for contact a sample. Each electrode pattern may extend substantially along the length of the biosensor strip to provide an electrical contact near the first end (22) and a conductive region electrically connecting the region of the electrode near the second end (24) to the electrical contact. The electrode layer (20) is made by electrically conductive materials. One or more conductive materials may be disposed on at least a portion of the base (10). The conductive materials such as, for example, gold, platinum, silver, iridium, carbon, copper, aluminum, gallium, iron, tantalum, titanium, zirconium, nickel, osmium, rhenium, rhodium, palladium, an organometallic, or metallic alloy.

In a preferred embodiment of the present invention, the electrode patterns are made by more than one manufacturing method and comprise a first electrode pattern (26) and a second electrode pattern (28). The first electrode pattern (26) is formed by providing a first electrically conductive material. Preferably, the first electrically conductive material is made by screen printed on the base (10). More preferably, the first electrically conductive material is carbon or carbon/silver. In a preferred embodiment of the present invention, the first electrode pattern (26) comprises a silver layer laid on the base (10) and a carbon layer laid on the silver layer. However, the first electrode pattern of the present invention is not limited to make by the two materials.

The second electrode pattern (28) is formed by providing a second electrically conductive material. Preferably, the second electrically conductive material is formed by sputtering coating. More preferably, the second electrically conductive material is consisting of a precious metal, such as gold, platinum, palladium or such like. The second electrically conductive material employs in the present invention has a more electrically conductive effect.

Furthermore, in another preferred embodiment of the present invention, the second electrically conductive material is then partially removing after sputtering coating a desired whole zone of the second electrically conductive material. After partially and selectively removing the second electrically conductive material, the second electrode pattern (28) is formed. Any conventional technique may be used to selectively remove the desired areas of the whole deposited zone to define the second electrode pattern (28), and examples of such conventional techniques include, but are not limited to, laser etching, chemical etching, dry etching, and the like.

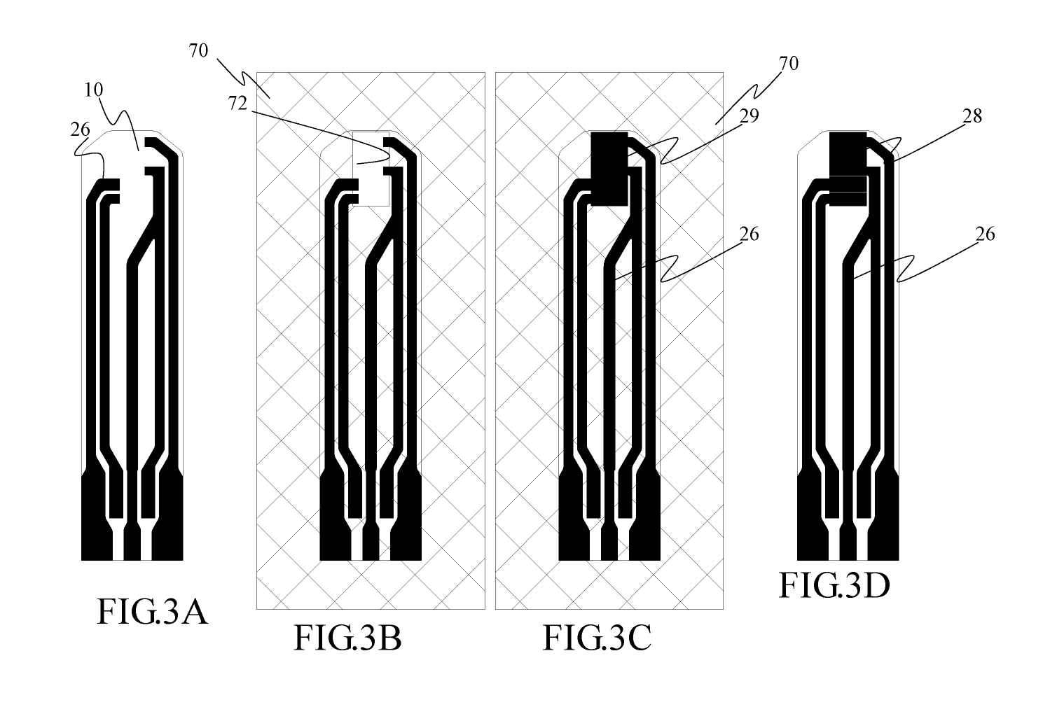

With further reference to FIGS. 3A to 3D, a preferred embodiment of a process for making the electrode layer is shown. Firstly referring to FIG. 3A, providing the first electrically conductive material on the base (10) made by screen printed to form the first electrode pattern (26). Then, a mask (70) is covered on the above. The mask (70) comprises a desired hollow zone (72) set on an appropriate site as shown in FIG. 3B. Preferably, the hollow zone (72) is used for sputtering the second electrically conductive material (29) as FIG. 3C shown. For forming the second electrode pattern (28), partially removing the second electrically conductive material using etching as FIG. 3D shown. In a preferred embodiment of the present invention, it is used laser etching for partially removing the second electrically conductive material to form the desired second electrode pattern (28). Preferably, etching step comprises removing four gaps to form five divided electrodes.

In a preferred embodiment of the present invention, the electrode layer (20) comprises a working electrode and a reference electrode respectively. Preferably, the electrode layer (20) comprises two electrode sets which respectively comprise a working electrode and a reference electrode. The two electrode sets respectively used for measuring different analyte. For instance, the electrode layer (20) includes a glucose detecting working electrode, a glucose detecting reference electrode, a hematocrit detecting working electrode, a hematocrit detecting reference electrode. For another instance, the electrode layer (20) includes a glucose detecting working electrode, a hematocrit detecting working electrode, a glucose/hematocrit detecting common reference electrode and a fill detecting electrode.

The spacer (30) is laid on partial base (10) and electrode layer (20) and exposed the first end (22) of the electrode layer (20) for contacting with a mating biosensor meter. Preferably, the spacer (30) comprises an opening (32) exposed the second end (24) of the electrode layer (20). In a preferred embodiment of the present invention, the opening (32) is set perpendicularly and opened to one end of the spacer (30). In another preferred embodiment of the present invention, the opening (32) can be set horizontally and opened to one side of the spacer (30). More preferably, the spacer (30) further comprises a separated element (34) formed corresponding to the opening (32) for dividing the opening (34) into two zones that are a first reaction zone (36) and a second reaction zone (38). Preferably, the spacer (30) could be formed by printing. The separated element (34) is used for preventing from reaction interfering at the first reaction zone (36) and the second reaction zone (38).

In another preferred embodiment of the present invention, the biosensor strip further comprises a second spacer (40) set on the spacer (30). The second spacer (40) comprises a second opening (42) corresponding to the opening (32) of the spacer (30). In another preferred embodiment of the present invention, the opening (32) of the spacer (30) and the second opening (42) of the second spacer (40) are defined to be a sample-receiving chamber.

The reaction reagent (50) is covered on the opening (32), and preferably, the reaction reagent (50) is covered on the first reaction zone (36) of the opening (32). The reaction reagent (40) is specific for the test to be performed by the strip and contains biological activated material (ex. Enzyme), enzyme cofactor, stabilizer (ex. macromolecule polymer), buffer and so on. Preferably, the reaction reagent (50) is not covered on the second reaction zone (38).

In a preferred embodiment of the present invention, the second electrode pattern is formed on the base (10) corresponding to the opening (32) of the spacer (30) or is formed corresponding to the reaction reagent (50). More preferably, a width of the second electrode pattern parallel to one end of the biosensor strip is wider than that of the opening (32) of the spacer (30).

In a preferred embodiment of the present invention, the first electrode pattern is formed almost corresponding to outside the opening (32) of the spacer (30). More preferably, the first electrode pattern is formed corresponding to outside the opening (32) of the spacer (30) and protruding a portion in the opening (32) of the spacer (30). In another preferred embodiment of the present invention, a portion of the first electrode pattern and a portion of the second electrode pattern are overlap.

The cover (60) is covered on the spacer (30) and has a hole (62) corresponding to the opening (32) of the spacer (30). Preferably, the hole (62) is corresponding far from the second end. Furthermore, the cover (60) further has a concave unit (64) that is formed corresponding to outside of the opening (32) of the spacer (30).

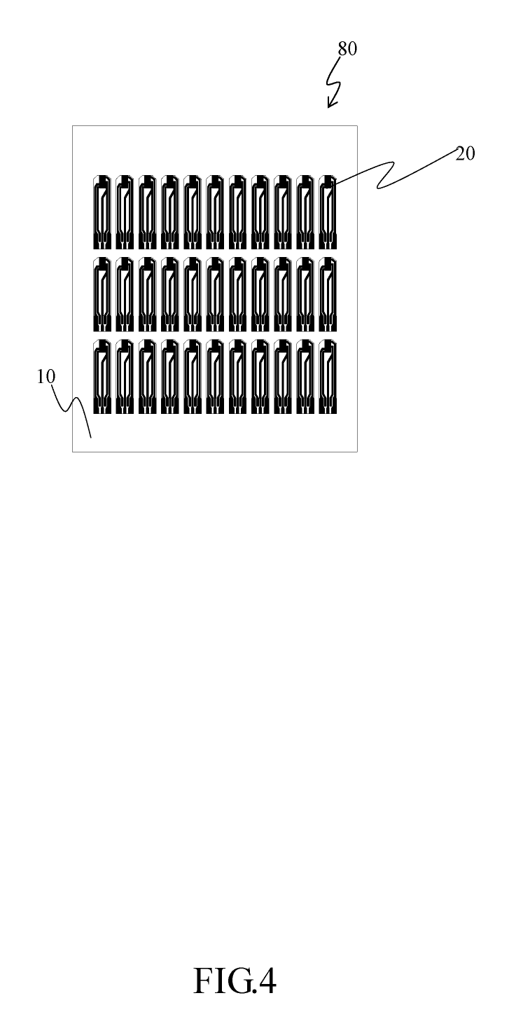

With reference to FIG. 4, a top view of a preferred embodiment of a sheet (80) of biosensor strips. The sheet (80) includes base (10) and an array of electrode layers (20) may be deposited on the base (10). Various layers may be added on the base (10) to form biosensor strips similar to that described in FIGS. 1 and 2. Biosensor strips may then be separated from the array of the biosensor strips form on the sheet (80) to produce multiple individual biosensor strips.

A plurality of electrode layers (20) may be formed on the base (10) and each electrode layer (20) comprises the first electrode pattern and the second electrode pattern. In a preferred embodiment of the present invention, the electrode layers are formed by previously described method.

Following the formation of one or more electrode layers (20) on the base (10), various layers may be added to the base (10) and the electrode layer (20) to form a laminate structure as shown in FIG. 1. Then, individual biosensor strips may be separated from sheet (80) via a cut process, and the outer shape of biosensor strip formed by the manufacturing process may be represented shown in FIGS. 1 and 2. Although FIG. 4 shows one configuration of electrode layer (20), it is understood that other configurations of electrode layer (20) may be used to form the biosensor strip.

As shown in FIG. 4, the electrode layer (20) may be arranged in multiple rows on the sheet (80). Further, the separation distance between the electrode layer (20) may be designed to permit a single cut to separate adjacent electrode layer (20) during the cut process. Besides, the sheet (80) includes a plurality of location points (not shown) of each biosensor strip. The location points may be used during one or more manufacturing processes to locate an element of biosensor strip relative to the sheet (80). One or more manufacturing steps may require location points to ensure precise alignment of laminate layers and/or other manufacturing processes, such as, for example, deposition of electrically conductive materials, mask alignment, reagent deposition, cut process, etc.

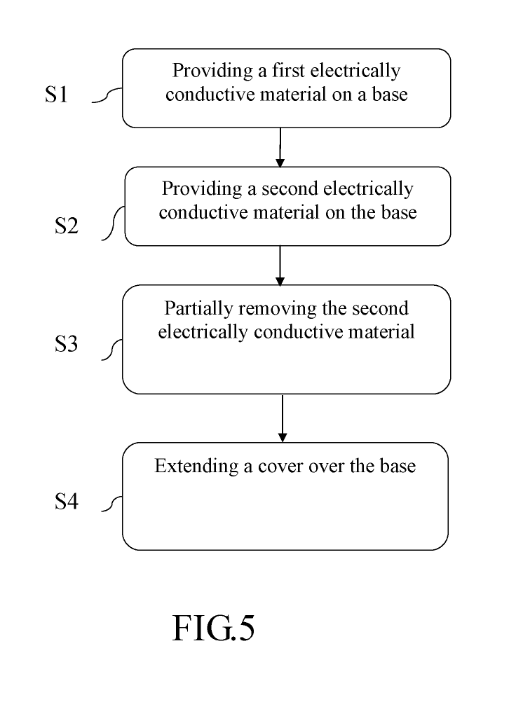

With further reference to FIG. 5, a block diagram of a process for making a biosensor strip of the present invention is shown. Firstly, providing a first electrically conductive material on a base (S1) is to form a first electrode pattern. In a preferred embodiment of the present invention, the first electrically conductive material is deposited on the base by screen printing. However, the present invention is not limited to use screen printing to deposit the first electrode pattern. Then, providing a second electrically conductive material on the base (S2) may be using sputtering coating. For forming a second electrode pattern, partially removing the second electrically conductive material (S3) by using laser etching. Further, extending a cover over the base (S4) and the cover and the base are cooperating to define a sample-receiving chamber.

In a preferred embodiment of the present invention, the second electrode pattern is deposited corresponding to the sample-receiving chamber. The second electrically conductive material may be has a more conductive effect than that of the first electrically conductive material. When the sample-receiving chamber received a blood sample, the blood sample then reacts with the reaction reagent and therefore the second electrode pattern electrically conduct an electrical change occurred in the reaction to the first electrode pattern. The mating biosensing meter contacts the first electrode pattern and detects the electrical change to compare and obtained a result.

The biosensor strip and the method for making thereof in accordance with the present invention have following advantages.

1. The biosensor strip in accordance with the present invention comprises an electrode pattern made by a more expensive material with high electrically conductive, such as gold, defined corresponding to the sample-receiving chamber and other electrode pattern outside the sample-receiving chamber made by a cheaper material that will decrease the cost.

2. The biosensor strip in accordance with the present invention employs the material with high electrically conductive to make the electrode pattern defined corresponding to the sample-receiving chamber that will increase detection accuracy.

3. The method for manufacturing a biosensor strip in accordance with the present invention does not employ sputtering coating method for manufacturing all electrode patterns and define a wider range for sputtering and then partially removing the sputtering material to form a desired pattern, and therefore, it will solve the disadvantage of conventional method that employs sputtering coating method for making all electrode patterns so that the desired pattern will smaller after time and time again to use the same mask.

4. The biosensor in accordance with the present invention effectively employs the second electrically conductive material, such as gold, and maintains the accuracy caused by the second electrically conductive material but decreases the cost.

Other embodiments of the invention will appear to those skilled in the art from consideration of the specification and practice of the invention disclosed herein. It is intended that the specification and examples to be considered as exemplary only, with a true scope and spirit of the invention being indicated by the following claims.

What is claimed is:

1. A method of manufacturing a biosensor strip, the method comprising the steps of:
providing a first electrically conductive material on a base to form a first electrode pattern;
providing a second electrically conductive material on the base by sputtering coating;
partially removing the second electrically conductive material to form a second electrode pattern; and
extending a cover over the base, the cover and the base cooperating to define a sample-receiving chamber that comprises a reaction reagent;
wherein the second electrode pattern is sized and positioned in the sample-receiving chamber.

2. The method as claimed in claim 1, wherein the second electrically conductive material is consisting of a precious metal and the first electrically conductive material is not consisting of a precious metal.

3. The method as claimed in claim 1, wherein the first electrically conductive material is provided on the base by a method except sputtering coating.

4. The method as claimed in claim 1, wherein the first electrically conductive material is screen printed on the base and the first electrode pattern is formed almost corresponding to outside the sample-receiving chamber.

5. The method as claimed in claim 4, wherein the first electrode pattern is formed corresponding to outside the sample-receiving chamber and protruding a portion in the sample-receiving chamber.

6. The method as claimed in claim 1, wherein partially removing the second electrically conductive material is using laser etching.

7. The method as claimed in claim 1, wherein a length of the second electrode pattern parallel to one end of the biosensor strip is greater than a width of the sample-receiving chamber.

8. The method as claimed in claim 1, wherein a portion of the first electrode pattern and a portion of the second electrode pattern are overlap.

9. A method of making a biosensor electrode pattern, comprising:
providing a first electrically conductive material on a base to form a first electrode pattern;
providing a second electrically conductive material which is not the same with the first electrically conductive material on the base by sputtering coating;
partially removing the second electrically conductive material from the base to form a second electrode pattern.

10. The method as claimed in claim 9, wherein the second electrode pattern is positioned suitable to contact a sample for detecting an analyte in the sample and partially removing the second electrically conductive material is using laser etching.

11. The method as claimed in claim 10, wherein the first electrically conductive material is screen printed on the base and the first electrode pattern is positioned almost corresponding to outside the second electrode pattern.

12. The method as claimed in claim 10, wherein a portion of the first electrode pattern and a portion of the second electrode pattern are overlap.

13. The method as claimed in claim 9, wherein the second electrically conductive material is consisting of a precious metal and the first electrically conductive material is not consisting of a precious metal.

14. A method of making a biosensor electrode pattern, comprising:
printing a first electrically conductive material on a flexible insulating substrate to form a first electrode pattern;
sputtering coating a second electrically conductive material on the flexible insulating substrate; and
ablating through a portion of the second electrically conductive material with a laser, to form a second electrode pattern.

15. The method as claimed in claim 14, wherein the second electrode pattern is defined to contact a sample for detecting an analyte in the sample.

16. The method as claimed in claim 14, wherein the second electrically conductive material is consisting of a precious metal and the first electrically conductive material is not consisting of a precious metal.

17. A method of making a biosensor strip, comprising:
forming an electrode pattern by the method of claim 14; and
cutting said substrate, to form a strip.

18. A biosensor strip comprising:
a base formed to include a first surface;
an electrode layer formed on the first surface;
a cover cooperating with the base to define a sample-receiving chamber; and
a reaction reagent coated on at least a portion of the sample-receiving chamber, and the sample-receiving chamber having a sample opening and sized to transport a liquid sample from the opening to the reaction reagent;
wherein the electrode layer comprises a first electrode pattern made by a first electrically conductive material positioned corresponding to outside the sample-receiving chamber, and a second electrode pattern made by a second electrically conductive material positioned corresponding to the sample-receiving chamber;
wherein the second electrically conductive material is consisting of a precious metal and the first electrically conductive material is not consisting of a precious metal.

19. The biosensor strip as claimed in claim 18, wherein the first electrically conductive material is screen printed on the base and the second electrically conductive material is sputtering coating on the base.

20. The biosensor strip as claimed in claim 19, wherein the second electrically conductive material sputtering coating on the base is then partially removed by laser etching to form the second electrode pattern.

21. The biosensor strip as claimed in claim 18, wherein a portion of the first electrode pattern and a portion of the second electrode pattern are overlap.

22. The biosensor strip as claimed in claim 18, wherein a length of the second electrode pattern parallel to one end of the biosensor strip is greater than a width of the sample-receiving chamber.
